(19) United States
(12) Patent Application Publication
(10) Pub. No.: US 2025/0221181 A1
(43) Pub. Date: Jul. 3, 2025

(54) Display Device

(71) Applicant: LG Display Co., Ltd., Seoul (KR)

(72) Inventors: Sungbin Shim, Yangsan-si (KR); Dahye Kwon, Seoul (KR); SangWon Lee, Paju-si (KR)

(21) Appl. No.: 18/917,949

(22) Filed: Oct. 16, 2024

(30) Foreign Application Priority Data
Dec. 28, 2023 (KR) 10-2023-0195723

(51) Int. Cl. H10K 59/123; H10K 59/131; H10K 59/80

(52) U.S. Cl. CPC H10K 59/123; H10K 59/131; H10K 59/8051

(57) ABSTRACT

A display device may include: a substrate; a transistor disposed on the substrate; a connection electrode electrically connected to a source electrode or a drain electrode of the transistor; a planarization layer disposed on the transistor and the connection electrode; a plurality of light-emitting elements disposed on the planarization layer; and a plurality of connection lines configured to adjoin the connection electrode and the plurality of light-emitting elements, in which the plurality of light-emitting elements includes a first light-emitting element and a second light-emitting element, and in which the plurality of connection lines are made of a conductive oxide, disposed between the first light-emitting element and the second light-emitting element, and configured to cover ends of anodes of the first and second light-emitting elements.

### CROSS-REFERENCE TO RELATED APPLICATION

This application claims the priority of Republic of Korea Patent Application No. 10-2023-0195723 filed on Dec. 28, 2023, which is hereby incorporated by reference in its entirety.

### BACKGROUND

### Field

The present specification relates to a display device, and more particularly, to a display device capable of minimizing or at least reducing a deterioration in reliability caused by repairing a defective subpixel.

### Description of the Related Art

As display devices used for a monitor of a computer, a television (TV) set, a mobile phone, and the like, there are an organic light-emitting display (OLED) device configured to autonomously emit, and a liquid crystal display (LCD) device that requires a separate light source.

The range of application of the display devices is diversified from the monitor of the computer and the TV set to personal mobile devices, and studies are being conducted on the display devices having wide display areas and having reduced volumes and weights.

Meanwhile, after the process of manufacturing the display device, an illumination inspection process may be performed on the display device to detect a defective subpixel having a dark spot defect or a bright spot defect. When the defective subpixel is detected, a repair process of separating an anode of the defective subpixel from a pixel circuit by using a laser may be performed.

### SUMMARY

An object to be achieved by the present specification is to provide a high-efficiency, low-power display device capable of minimizing or at least reducing a deterioration in reliability of a peripheral portion caused by physical deformation of a connection line irradiated with laser beams during a repair process.

Another object to be achieved by the present specification is to provide a high-quality display device in which a reduction in light-emitting area is minimized or at least reduced by using a contact hole as a repair point without adding a separate configuration for repair.

Objects of the present disclosure are not limited to the above-mentioned objects, and other objects, which are not mentioned above, can be clearly understood by those skilled in the art from the following descriptions.

In order to achieve the above-mentioned object, a display device according to an exemplary embodiment of the present disclosure may include: a substrate; a transistor disposed on the substrate; a connection electrode electrically connected to a source electrode or a drain electrode of the transistor; a planarization layer disposed on the transistor and the connection electrode; a plurality of light-emitting elements disposed on the planarization layer; and a plurality of connection lines configured to adjoin the connection electrode and the plurality of light-emitting elements, in which the plurality of light-emitting elements includes a first light-emitting element and a second light-emitting element, and in which the plurality of connection lines are made of a conductive oxide, disposed between the first light-emitting element and the second light-emitting element, and configured to cover an end of an anode of the first light-emitting element and an end of an anode of the second light-emitting element.

In order to achieve the above-mentioned object, a display device according to another exemplary embodiment of the present disclosure may include: a substrate on which a plurality of subpixels are disposed; a transistor disposed in each of the plurality of subpixels on the substrate; a connection electrode electrically connected to a source electrode or a drain electrode of the transistor; a planarization layer disposed on the transistor and the connection electrode; a first light-emitting element and a second light-emitting element disposed on the planarization layer in one subpixel; and a plurality of connection lines configured to electrically connect the first light-emitting element, the second light-emitting element, and the connection electrode, in which the plurality of connection lines are made of a conductive oxide, and configured to cover an end of an anode of the first light-emitting element and an end of an anode of the second light-emitting element disposed in the one subpixel, and in which at least one of the plurality of connection lines comprises a low-resistance portion, and a high-resistance portion having a higher resistance value than the low-resistance portion.

Other detailed matters of the exemplary embodiments are included in the detailed description and the drawings.

According to the present specification, it is possible to minimize or at least reduce a deterioration in reliability of the display device that occurs during the repair process.

According to the present specification, it is possible to minimize or at least reduce a reduction in light-emitting area while providing the configuration capable of being repaired.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a top plan view of a display device according to an embodiment of the present specification;

FIGS. 2A and 2B are enlarged top plan views of a subpixel in which both a first light-emitting element and a second light-emitting element are normal in the display device according to an embodiment of the present specification;

FIG. 2C is a cross-sectional view taken along line A-A′ in FIG. 2B according to an embodiment of the present specification;

FIG. 3A is an enlarged top plan view of a subpixel in which a first light-emitting element is defective in the display device according to an embodiment of the present specification;

FIG. 3B is a cross-sectional view taken along line B-B′in FIG. 3A according to an embodiment of the present specification;

FIG. 3C is an enlarged view of area C in FIG. 3B according to an embodiment of the present specification;

FIG. 4A is an enlarged top plan view of a subpixel in which a second light-emitting element is defective in the display device according to an embodiment of the present specification;

FIG. 4B is a cross-sectional view taken along line D-D′ in FIG. 4A according to an embodiment of the present specification;

FIG. 5A is an enlarged top plan view of a subpixel in which both a first light-emitting element and a second light-emitting element are defective in the display device according to the embodiment of the present specification;

FIG. 5B is a cross-sectional view taken along line E-E′ in FIG. 5A according to an embodiment of the present specification;

FIGS. 6A and 6B are enlarged top plan views of a subpixel in which both a first light-emitting element and a second light-emitting element are normal in a display device according to another embodiment of the present specification;

FIG. 6C is a cross-sectional view taken along line F-F′ in FIG. 6B according to an embodiment of the present specification;

FIG. 7A is an enlarged top plan view of a subpixel in which a first light-emitting element is defective in the display device according to another embodiment of the present specification;

FIG. 7B is a cross-sectional view taken along line G-G′ in FIG. 7A according to an embodiment of the present specification;

FIG. 7C is an enlarged view of area H in FIG. 7B according to an embodiment of the present specification;

FIG. 8A is an enlarged top plan view of a subpixel in which a second light-emitting element is defective in the display device according to another embodiment of the present specification;

FIG. 8B is a cross-sectional view taken along line I-I′ in FIG. 8A according to an embodiment of the present specification;

FIG. 9A is an enlarged top plan view of a subpixel in which a first light-emitting element and a second light-emitting element are defective in the display device according to another embodiment of the present specification; and

FIG. 9B is a cross-sectional view taken along line J-J′ in FIG. 9A according to an embodiment of the present specification.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, ‘comprising’ used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

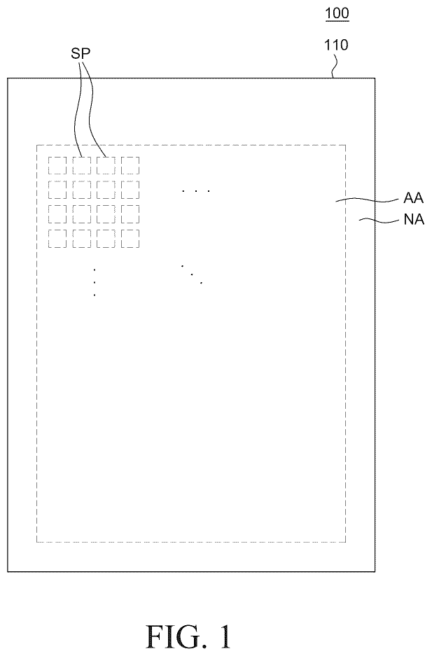

FIG. 1 is a top plan view of a display device according to an embodiment of the present specification. For convenience of description, FIG. 1 illustrates a substrate 110 and a plurality of subpixels SP among various constituent elements of a display device 100.

The substrate 110 is a support member for supporting other constituent elements of the display device 100. The substrate 110 includes a display area AA and a non-display area NA. The substrate 110 may be made of an insulating material. For example, the substrate 110 may be made of glass, resin, or the like. In addition, the substrate 110 may include plastic such as polymer or polyimide (PI) and may be made of a material having flexibility.

The display area AA of the substrate 110 is an area in which images are displayed. The display area AA may include the plurality of subpixels SP for displaying images, and a pixel circuit configured to operate the plurality of subpixels SP. The pixel circuit may include various thin-film transistors, storage capacitors, lines, and the like for operating the subpixels SP.

The non-display area NA is an area in which no image is displayed. Various lines, drive ICs, and the like for operating the subpixels SP disposed in the display area AA are disposed in the non-display area NA. For example, various drive ICs such as a gate driver IC and a data driver IC may be disposed in the non-display area NA.

Meanwhile, FIG. 1 illustrates that the non-display area NA surrounds the display area AA. However, the non-display area NA may be an area extending from one side of the display area AA. However, the present specification is not limited thereto.

The plurality of subpixels SP are disposed in the display area AA of the substrate 110. Each of the plurality of subpixels SP is an individual unit configured to emit light. A light-emitting element and a pixel circuit are formed in each of the plurality of subpixels SP. For example, the plurality of subpixels SP may include a red subpixel, a green subpixel, a blue subpixel, and a white subpixel. However, the present specification is not limited thereto.

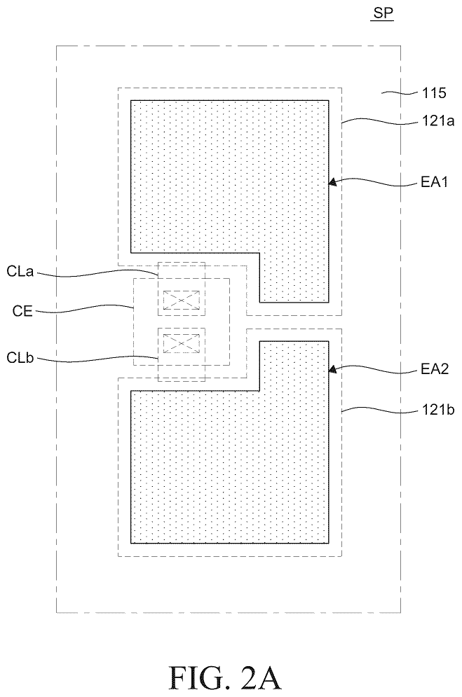

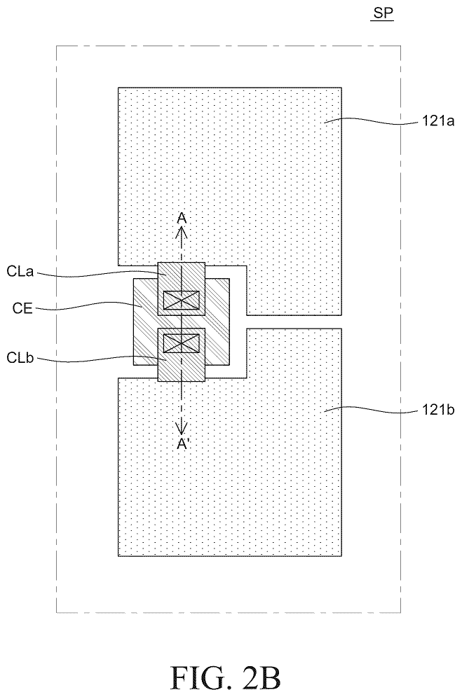

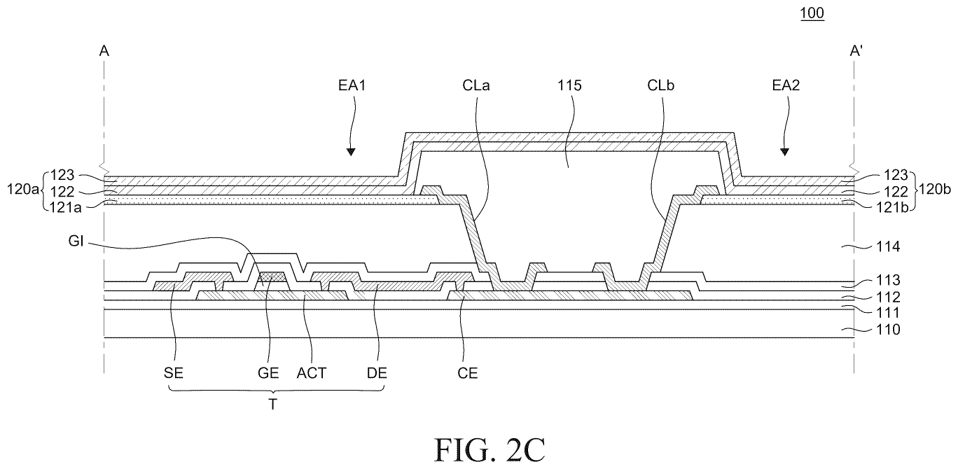

Hereinafter, a subpixel, in which all the plurality of light-emitting elements are normal in the display device according to the embodiment of the present specification, will be described in more detail with reference to FIGS. 2A to 2C.

FIGS. 2A and 2B are enlarged top plan views of a subpixel in which both a first light-emitting element and a second light-emitting element are normal in the display device according to an embodiment of the present specification. FIG. 2C is a cross-sectional view taken along line A-A′ in FIG. 2B according to an embodiment of the present specification. FIG. 2A is a top plan view of the subpixel in which both the first light-emitting element and the second light-emitting element are normal among the plurality of subpixels. For convenience of illustration, FIG. 2A illustrates only a first anode 121a, a second anode 121b, a connection electrode CE, a first connection line CLa, a second connection line CLb, and a bank 115 among various constituent elements of the display device 100. For convenience of description, FIG. 2B is a view that does not illustrate the bank 115 in FIG. 2A.

The plurality of subpixels SP each include a light-emitting area and a circuit area.

The light-emitting area is an area that may independently emit light with a single type of color. The light-emitting element may be disposed in the light-emitting area. The plurality of subpixels SP may include a first subpixel, a second subpixel, a third subpixel, and a fourth subpixel that emit light beams with different colors. For example, the light-emitting area of the first subpixel may be a red light-emitting area for emitting red light, the light-emitting area of the second subpixel may be a white light-emitting area for emitting white light, the light-emitting area of the third subpixel may be a blue light-emitting area for emitting blue light, and the light-emitting area of the fourth subpixel may be a green light-emitting area for emitting green light. However, the present specification is not limited thereto, and the colors of the light beams implemented in the plurality of light-emitting areas and the arrangement of the plurality of light-emitting areas may vary in accordance with design.

The circuit area is an area in which the pixel circuit for operating the plurality of light-emitting elements is disposed. A plurality of transistors and capacitors may be disposed in the circuit area. For example, in case that the pixel circuit of the subpixel SP has a 3T1C structure, three transistors and one storage capacitor may be disposed. However, the present specification is not limited thereto.

With reference to FIGS. 2A and 2B, the plurality of light-emitting areas EA1 and EA2 are disposed in each of the subpixels SP. Further, in each of the subpixels SP, the plurality of light-emitting elements 120a and 120b are disposed to respectively correspond to the plurality of light-emitting areas EA1 and EA2.

The plurality of light-emitting areas EA1 and EA2 includes a first light-emitting area EA1 and a second light-emitting area EA2. The plurality of light-emitting elements 120a and 120b includes a first light-emitting element 120a and a second light-emitting element 120b. The first light-emitting element 120a is disposed to correspond to the first light-emitting area EA1, and the second light-emitting element 120b is disposed to correspond to the second light-emitting area EA2.

The plurality of light-emitting areas EA1 and EA2 may be defined by the bank 115 disposed to cover ends of anodes 121a and 121b of the plurality of light-emitting elements 120a and 120b. That is, the first light-emitting area EA1 may be defined as an area surrounded by the bank 115 disposed to cover the end of the first anode 121a of the first light-emitting element 120a. Further, the second light-emitting area EA2 may be defined as an area surrounded by the bank 115 disposed to cover the end of the second anode 121b of the second light-emitting element 120b.

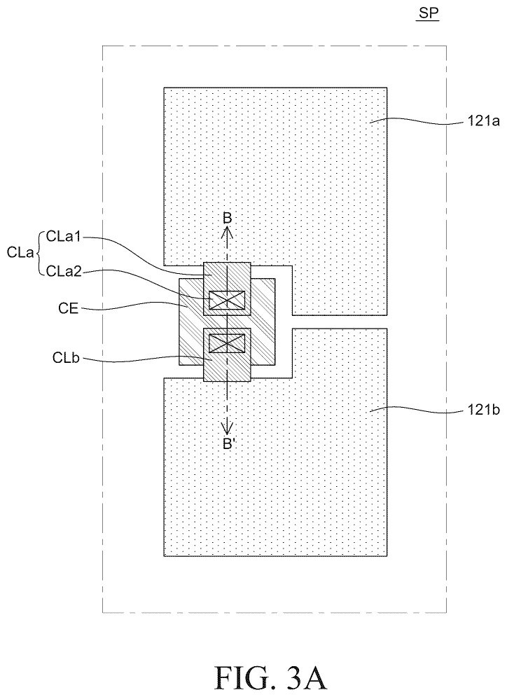

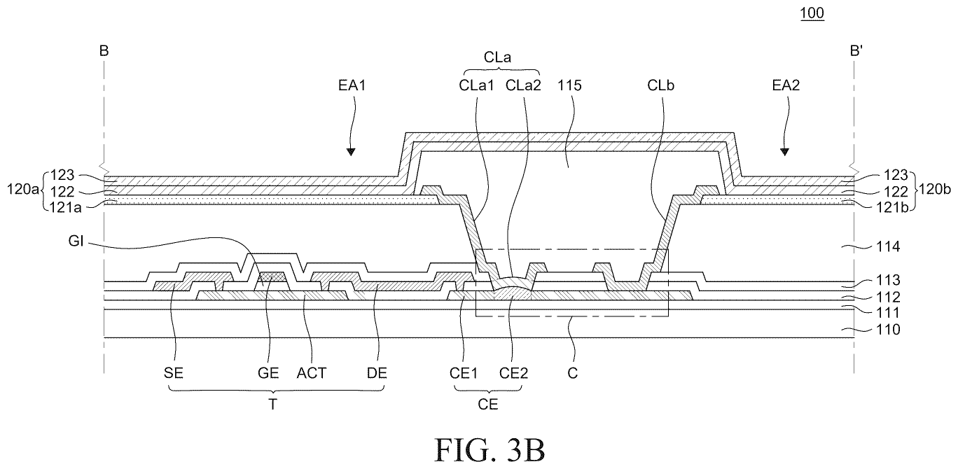

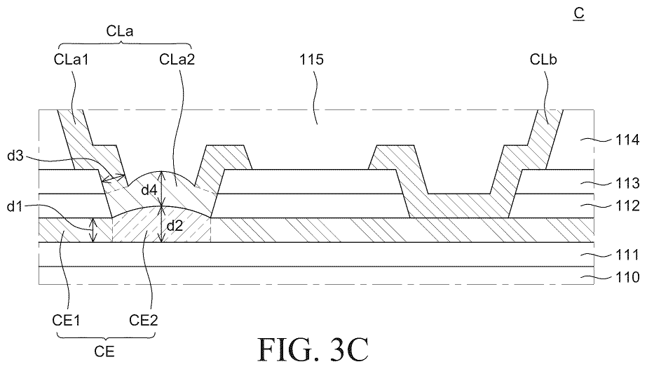

The first light-emitting element 120a and the second light-emitting element 120b emit light beams with the same color. The first light-emitting element 120a and the second light-emitting element 120b may be disposed to share one pixel circuit. Therefore, the first light-emitting element 120a and the second light-emitting element 120b may be configured to repair a luminance defect or a dark spot defect of the subpixel SP. However, a method of repairing a defective subpixel SP will be described below in detail with reference to FIGS. 3A to 5B.

With reference to FIG. 2C, a buffer layer 111, a gate insulation layer GI, an inorganic insulation layer 112, a transistor T, the connection electrode CE, a passivation layer 113, a planarization layer 114, the first light-emitting element 120a, the second light-emitting element 120b, the first connection line CLa, the second connection line CLb, and the bank 115 are sequentially disposed on the substrate 110 in the subpixel SP.

The buffer layer 111 is disposed on the substrate 110. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present specification is not limited thereto, and the buffer layer 111 may be excluded in accordance with the type of substrate 110 or the type of thin-film transistor.

The transistor T and the connection electrode CE are disposed in the circuit area in each of the plurality of subpixels SP. The transistor T includes a gate electrode GE, a source electrode SE, a drain electrode DE, and an active layer ACT.

First, the active layer ACT is disposed on the buffer layer 111. The active layer ACT may be made of a transparent oxide semiconductor, such as indium gallium zinc oxide (IGZO), or a semiconductor material such as amorphous silicon or polysilicon. However, the present specification is not limited thereto. For example, in case that the active layer ACT is made of oxide semiconductor, the active layer ACT may include a channel area, a source area, and a drain area, and the source area and the drain area may be areas having conductivity. However, the present specification is not limited thereto.

With reference to FIG. 2C, the connection electrode CE is disposed on the buffer layer 111. The connection electrode CE is disposed on the same layer as the active layer ACT and disposed to be spaced apart from the active layer ACT. The connection electrode CE may be made of the same material as the active layer ACT and formed by the same process as the active layer ACT. However, the present specification is not limited thereto. For example, the connection electrode CE may be made of a transparent oxide semiconductor material such as indium gallium zinc oxide (IGZO). However, the present specification is not limited thereto.

In this case, the connection electrode CE may be configured to have conductivity so that the connection electrode CE serves as an electrode. For example, the connection electrode CE may be patterned by the same process as the active layer ACT and then configured to have conductivity through a process, such as dry etching, that makes the electrode conductive. Alternatively, the connection electrode CE may be configured to have conductivity by further adding a transparent conductive material, such as indium zinc oxide (IZO), onto a transparent oxide semiconductor material patterned by the same process as the active layer ACT. However, the present specification is not limited thereto.

Meanwhile, in case that both the first light-emitting element 120a and the second light-emitting element 120b disposed in the subpixel SP are normal, the repair process is not performed on the connection electrode CE disposed in the subpixel SP, such that all the areas may have conductivity.

The connection electrode CE is electrically connected to the source electrode SE or the drain electrode DE in each of the plurality of subpixels SP. For example, as illustrated in FIG. 2C, the drain electrode DE may be electrically connected to the connection electrode CE through a contact hole formed in the insulation layer 112. Further, the first connection line CLa and the second connection line CLb, which are respectively connected to the first light-emitting element 120a and the second light-emitting element 120b, are disposed on the connection electrode CE. Therefore, the connection electrode CE may electrically connect the first light-emitting element 120a, the second light-emitting element 120b, and the transistor T.

The gate insulation layer GI is disposed on the active layer ACT and the connection electrode CE. The gate insulation layer GI may be a layer for insulating the gate electrode GE and the active layer ACT and made of an insulating material. For example, the gate insulation layer GI may be configured as a single layer or multilayer made of silicon oxide (SiOx) or silicon nitride (SiNx). However, the present specification is not limited thereto.

Meanwhile, FIG. 2C illustrates that the gate insulation layer GI is disposed only in an area that overlaps the gate electrode GE. However, the gate insulation layer GI may be disposed in the entire area of the substrate 110. However, the present specification is not limited thereto.

The gate electrode GE is disposed on the gate insulation layer GI. The gate electrode GE is disposed on the gate insulation layer GI and overlaps the active layer ACT. The gate electrode GE may be made of an electrically conductive material, for example, copper (Cu), aluminum (Al), molybdenum (Mo), nickel (Ni), titanium (Ti), chromium (Cr), or an alloy thereof. However, the present specification is not limited thereto.

The insulation layer 112 is disposed on the active layer ACT, the connection electrode CE, and the gate electrode GE. The insulation layer 112 may be a layer for insulating the active layer ACT, the gate electrode GE, the source electrode SE, and the drain electrode DE and made of an insulating material. For example, the insulation layer 112 may be made of an inorganic insulating material. For example, the insulation layer 112 may be configured as a single layer or multilayer made of silicon oxide (SiOx) or silicon nitride (SiNx). However, the present specification is not limited thereto.

The source electrode SE and the drain electrode DE is disposed on the insulation layer 112 and spaced apart from each other. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present specification is not limited thereto.

For example, the source electrode SE may be electrically connected to a high-potential power line through contact holes formed in the insulation layer 112 and the buffer layer 111.

The drain electrode DE is connected to the connection electrode CE through a contact hole formed in the insulation layer 112. Therefore, the drain electrode DE may be electrically connected to the connection electrode CE, the first connection line CLa, the second connection line CLb, the first anode 121a, and the second anode 121b and transmit drive currents to the first light-emitting element 120a and the second light-emitting element 120b.

Meanwhile, although not illustrated in the drawings, the storage capacitor may be further disposed in the circuit area in each of the plurality of subpixels SP. The storage capacitor may store a voltage between the gate electrode GE and the source electrode SE of the transistor T so that the light-emitting element may continuously maintain the same state during a single frame. The storage capacitor may include a first capacitor electrode and a second capacitor electrode. However, the present specification is not limited thereto.

In addition, although not illustrated in the drawings, a light-blocking layer may be further disposed below the active layer ACT. The light-blocking layer may block light entering the active layer ACT. For example, in case that the light is emitted to the active layer ACT, a leakage current occurs, which may degrade the reliability of the transistor T. Therefore, the light-blocking layer made of an opaque conductive material may be disposed below the active layer ACT and block light entering the active layer ACT from the lower side of the substrate 110, which may improve the reliability of the transistor T.

Next, the passivation layer 113 is disposed on the transistor T and the connection electrode CE. The passivation layer 113 is an insulation layer for protecting the components disposed below the passivation layer 113. For example, the passivation layer 113 may be configured as a single layer or multilayer made of silicon oxide (SiOx) or silicon nitride (SiNx). However, the present specification is not limited thereto. In addition, the passivation layer 113 may be excluded in accordance with the embodiments.

The planarization layer 114 is disposed on the passivation layer 113. The planarization layer 114 is an insulation layer for planarizing an upper portion of the substrate 110 on which the transistor T and the connection electrode CE are disposed. The planarization layer 114 may be an organic layer made of an organic material. For example, the planarization layer 114 may be configured as a single layer or multilayer made of an organic material, for example, polyimide or photo acrylic. However, the present specification is not limited thereto.

The plurality of light-emitting elements 120a and 120b are disposed on the planarization layer 114 in each of the plurality of subpixels SP. The plurality of light-emitting elements 120a and 120b include the first light-emitting element 120a and the second light-emitting element 120b. The first light-emitting element 120a and the second light-emitting element 120b are disposed on the planarization layer 114 in each of the plurality of subpixels SP. The plurality of light-emitting elements 120a and 120b include the anodes 121a and 121b, light-emitting layers 122, and cathodes 123. That is, the first light-emitting element 120a includes the first anode 121a, the light-emitting layer 122, and the cathode 123, and the second light-emitting element 120b includes the second anode 121b, the light-emitting layer 122, and the cathode 123.

With reference to FIGS. 2A to 2C, the first anode 121a and the second anode 121b are disposed on the planarization layer 114 to respectively correspond to the first light-emitting area EA1 and the second light-emitting area EA2. Because the first anode 121a and the second anode 121b supply positive holes to the light-emitting layers 122, the first anode 121a and the second anode 121b may be made of an electrically conductive material with a high work function. For example, the first anode 121a and the second anode 121b may each be made of a transparent conductive material such as indium tin oxide (ITO) or indium zinc oxide (IZO). However, the present specification is not limited thereto.

Meanwhile, in case that the display device 100 according to the embodiment of the present specification is a top emission type display device, a reflective layer, which is made of a metallic material, e.g., a material such as aluminum (Al) or silver (Ag) with excellent reflection efficiency, may be additionally provided below the first anode 121a and the second anode 121b so that the light emitted from the light-emitting layer 122 is reflected by the first anode 121a and the second anode 121b and propagates upward, i.e., toward the cathode 123. For example, the first anode 121a and the second anode 121b may each have a structure in which indium tin oxide (ITO), silver (Ag), and indium tin oxide (ITO) are sequentially stacked. However, the present specification is not limited thereto.

The bank 115 is disposed on the first anode 121a and the second anode 121b. The bank 115 may be disposed in the remaining area excluding the first light-emitting area EA1 and the second light-emitting area EA2. The bank 115 may be disposed at the boundaries between the plurality of subpixels SP and disposed in the circuit areas of the plurality of subpixels SP and reduce a color mixture of light beams emitted from the plurality of subpixels SP. The bank 115 may include an opening portion through which the first anode 121a and the second anode 121b, which correspond to the first light-emitting area EA1 and the second light-emitting area EA2, are at least partially exposed. The bank 115 may be made of an organic insulating material. For example, the bank 115 may be made of polyimide-based resin, acryl-based resin, or benzocyclobutene (BCB)-based resin. However, the present specification is not limited thereto.

The light-emitting layer 122 is disposed on the first anode 121a, the second anode 121b, and the bank 115 in the first light-emitting area EA1 and the second light-emitting area EA2. For example, the light-emitting layer 122 may be configured as a single layer over the plurality of subpixels SP. That is, the light-emitting layers 122 of the plurality of subpixels SP may be connected to and integrated with one another. The light-emitting layer 122 may be configured as a single light-emitting layer. The light-emitting layer 122 may also have a structure in which a plurality of light-emitting layers configured to emit light beams with different colors is stacked. The light-emitting layer 122 may further include organic material layers such as a hole injection layer, a hole transport layer, an electron transport layer, and an electron injection layer. For example, in case that the light-emitting layer 122 is the light-emitting layer configured to emit white light, the light beam emitted from the light-emitting layer 122 may be converted into light beams with various colors by a plurality of color filters. However, the present specification is not limited thereto.

The cathode 123 is disposed on the light-emitting layer 122. Because the cathode 123 supplies electrons to the light-emitting layer 122, the cathode 123 may be made of an electrically conductive material having a low work function. The cathode 123 may be configured as a single layer over the plurality of subpixels SP. That is, the cathodes 123 of the plurality of subpixels SP may be connected to and integrated with one another. For example, the cathode 123 may be made of an electrically transparent conductive material such as indium tin oxide (ITO) or indium zinc oxide (IZO) or made of an alloy of ytterbium (Yb). The cathode 123 may further include a metal doping layer. However, the present specification is not limited thereto. Meanwhile, although not illustrated in the drawings, the cathode 123 of each of the first light-emitting element 120a and the second light-emitting element 120b may be electrically connected to a low-potential power line and supplied with a low-potential power voltage.

In each of the subpixels, the first connection line CLa and the second connection line CLb are disposed between the first light-emitting element 120a and the second light-emitting element 120b and disposed at an end of the first anode 121a and an end of the second anode 121b. That is, the first connection line CLa is disposed at the end of the first anode 121a, and the second connection line CLb is disposed at the end of the second anode 121b. Therefore, the first connection line CLa and the second connection line CLb may be configured to adjoin the connection electrode CE, the first light-emitting element 120a, and the second light-emitting element 120b and electrically connect the transistor T, the first light-emitting element 120a, and the second light-emitting element 120b.

Meanwhile, the first connection line CLa and the second connection line CLb are disposed to be spaced apart from each other. Therefore, the first connection line CLa and the second connection line CLb may be configured to be electrically connected to different light-emitting elements. That is, the first connection line CLa is electrically connected to the first light-emitting element 120a, and the second connection line CLb is electrically connected to the second light-emitting element 120b.

With reference to FIGS. 2A to 2C, the first connection line CLa and the second connection line CLb are in contact with a top surface of the connection electrode CE through contact holes formed in the passivation layer 113 and the planarization layer 114. Therefore, the first connection line CLa and the second connection line CLb may be electrically connected to the connection electrode CE. The first connection line CLa is disposed to extend onto the connection electrode CE from the end of the first anode 121a. The second connection line CLb is disposed to extend onto the connection electrode CE from the end of the second anode 121b.

In each of the subpixels, the first connection line CLa and the second connection line CLb may be electrically connected to one connection electrode CE. That is, the first light-emitting element 120a and the second light-emitting element 120b may be electrically connected to one transistor T. Therefore, the first connection line CLa and the second connection line CLb may each serve as a repair part that repairs the subpixel SP with a bright spot defect or a dark spot defect by selectively blocking the electrical connection between the first light-emitting element 120a, the second light-emitting element 120b, and the transistor T. However, a method of repairing a defective subpixel SP with a bright spot defect or a dark spot defect will be described below in detail with reference to FIGS. 3A to 5B.

Meanwhile, FIGS. 2A to 2C illustrate a normal subpixel SP that does not have a defect and is not subjected to the repair process. In this case, if both the first light-emitting element 120a and the second light-emitting element 120b disposed in the subpixel SP are normal, the repair process is not performed on the first connection line CLa and the second connection line CLb disposed in the subpixel SP, such that both the first connection line CLa and the second connection line CLb may be conductive.

The first connection line CLa and the second connection line CLb may be made of a transparent conductive oxide. For example, the first connection line CLa and the second connection line CLb may each be made of a transparent conductive material, such as indium zinc oxide (IZO) and indium gallium zinc oxide (IGZO), including indium (In). However, the present specification is not limited thereto.

Meanwhile, during a process of manufacturing the display device 100, a step of forming the first connection line CLa and the second connection line CLb may be performed after a step of forming the connection electrode CE, the first anode 121a, and the second anode 121b. Therefore, the first connection line CLa and the second connection line CLb may be disposed on the connection electrode CE, the first anode 121a, and the second anode 121b in a crystallized state.

For example, the step of forming the connection electrode CE, the first anode 121a, and the second anode 121b may include a step of patterning materials, which constitute the connection electrode CE, the first anode 121a, and the second anode 121b, and a step of crystallizing the connection electrode CE, the first anode 121a, and the second anode 121b through heat treatment. Further, the step of forming the first connection line CLa and the second connection line CLb may be performed after the step of crystallizing the connection electrode CE, the first anode 121a, and the second anode 121b. Therefore, because the connection electrode CE, the first anode 121a, and the second anode 121b are in the crystallized state, damage caused by etching materials and the like may be minimized even though wet etching is used for a step of disposing the first connection line CLa and the second connection line CLb on the connection electrode CE, the first anode 121a, and the second anode 121b.

Meanwhile, although not illustrated in the drawings, an encapsulation layer, an encapsulation substrate, and a plurality of color filters may be further disposed on the first light-emitting element 120a and the second light-emitting element 120b.

The encapsulation layer is disposed on the first light-emitting element 120a and the second light-emitting element 120b. The encapsulation layer may cover the first light-emitting element 120a and the second light-emitting element 120b and protect the first light-emitting element 120a and the second light-emitting element 120b from external moisture, oxygen, impact, and the like. The encapsulation layer may be formed by alternately stacking a plurality of inorganic layers and a plurality of organic layers. For example, the inorganic layer may be made of an inorganic material such as silicon nitride (SiNx), silicon oxide (SiOx), or aluminum oxide (AlOx). The organic layer may be made of epoxy-based polymer or acrylic polymer. However, the present specification is not limited thereto.

The encapsulation substrate is disposed on the encapsulation layer. The encapsulation substrate, together with the encapsulation layer, may protect the first light-emitting element 120a and the second light-emitting element 120b from external moisture, oxygen, impact, and the like. For example, the encapsulation substrate may be made of a transparent insulating material. However, the encapsulation substrate may be made of a metallic material. However, the present specification is not limited thereto.

The plurality of color filters may be disposed on the first light-emitting element 120a and the second light-emitting element 120b. For example, the plurality of color filters may be disposed between the encapsulation layer and the encapsulation substrate. However, the present specification is not limited thereto.

The plurality of color filters may include a red color filter, a green color filter, a blue color filter, and the like. For example, the red color filter may be disposed in the light-emitting area of the first subpixel and convert white light, which is emitted from the first subpixel, into red light. The blue color filter may be disposed in the light-emitting area of the third subpixel and convert white light, which is emitted from the third subpixel, into blue light. The green color filter may be disposed in the light-emitting area of the fourth subpixel and convert white light, which is emitted from the fourth subpixel, into green light. Further, no separate color filter may be disposed on the second subpixel that is a white subpixel. White light, which is emitted from the light-emitting element of the second subpixel, may propagate to the outside of the display device 100 in an intact manner and display a white image.

Hereinafter, a method of repairing a subpixel SP in which a defective light-emitting element is disposed in the display device according to the embodiment of the present specification will be described in more detail with reference to FIGS. 3A to 5B.

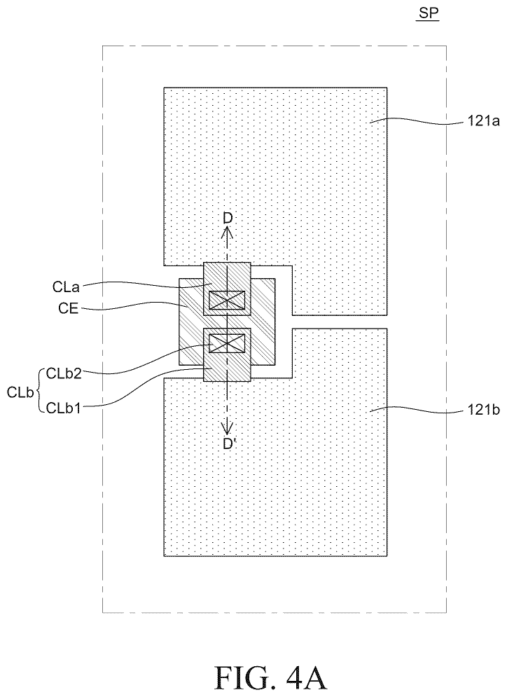

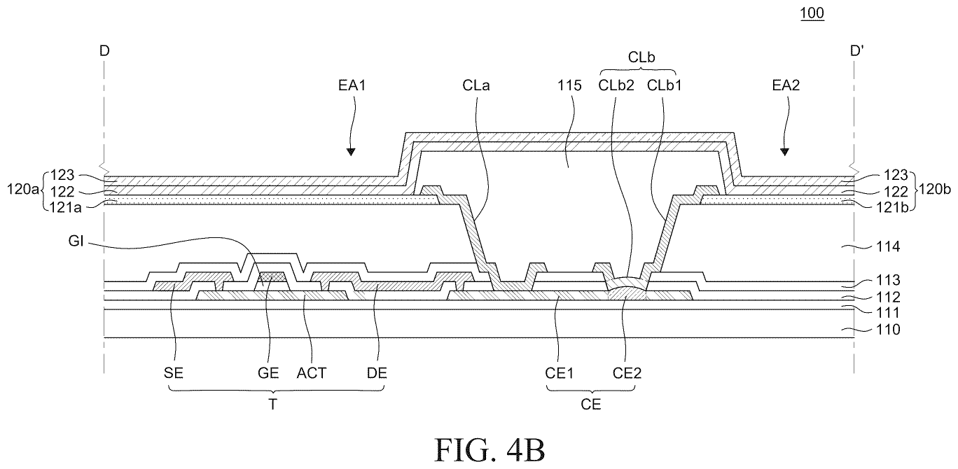

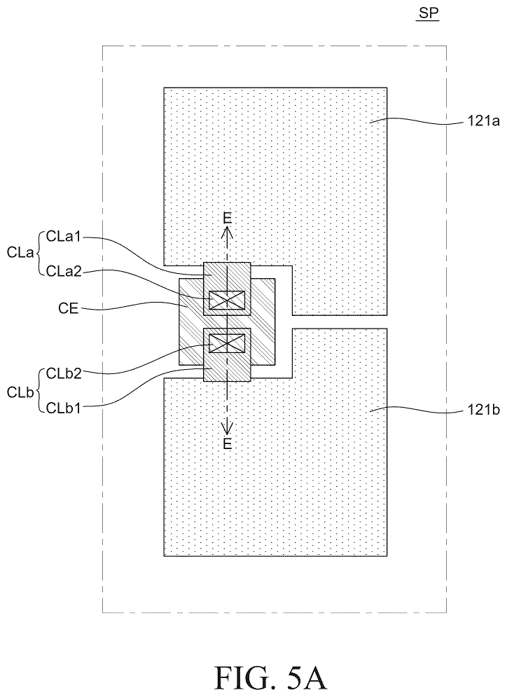

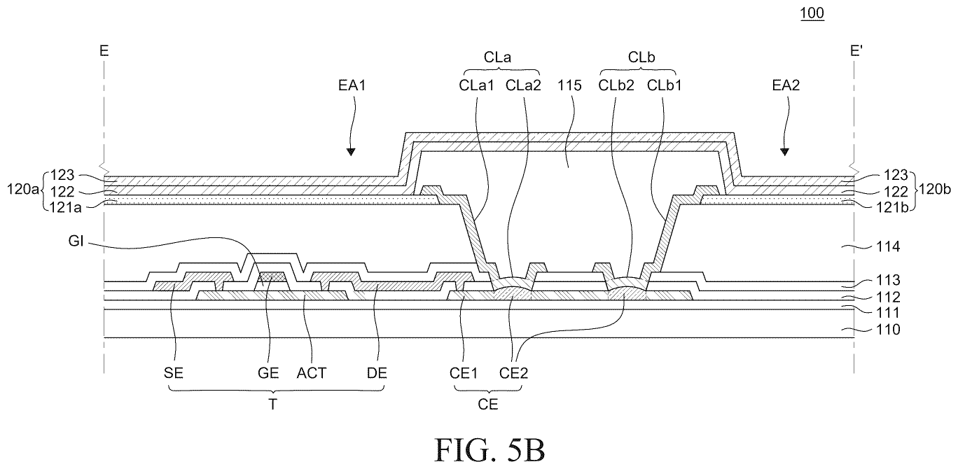

FIG. 3A is an enlarged top plan view of a subpixel in which a first light-emitting element is defective in the display device according to an embodiment of the present specification. FIG. 3B is a cross-sectional view taken along line B-B′ in FIG. 3A according to an embodiment of the present specification. FIG. 3C is an enlarged view of area C in FIG. 3B according to an embodiment of the present specification. FIG. 4A is an enlarged top plan view of a subpixel in which a second light-emitting element is defective in the display device according to an embodiment of the present specification. FIG. 4B is a cross-sectional view taken along line D-D′ in FIG. 4A according to an embodiment of the present specification. FIG. 5A is an enlarged top plan view of a subpixel in which both a first light-emitting element and a second light-emitting element are defective in the display device according to an embodiment of the present specification. FIG. 5B is a cross-sectional view taken along line E-E′ in FIG. 5A according to an embodiment of the present specification.

For example, during the process of manufacturing the display device, a short circuit (A-C short) may occur between the anode and the cathode by foreign substances remaining between the anode and the cathode of the light-emitting element, thus there may occur a dark spot defect in which electric current is not applied to the light-emitting element or a bright spot defect in which the light-emitting element continuously emits light. Therefore, it is possible to repair the display device so that a bright spot defect or a dark spot defect of a defective light-emitting element in a final product is not visually recognized by electrically disconnecting the transistor and the light-emitting element that has a bright spot defect or a dark spot defect among the plurality of light-emitting elements connected to one transistor.

With reference to FIGS. 3A to 5B, in the display device 100 according to the embodiment of the present specification, the connection electrode CE of the subpixel SP, which has a bright spot defect or a dark spot defect, includes a first resistance portion CE1 and a second resistance portion CE2.

The first resistance portion CE1 is a portion of the connection electrode CE that is not subjected to a laser irradiation process for repair. The entire area of the first resistance portion CE1 may have conductivity, like the connection electrode CE of the normal subpixel SP.

The second resistance portion CE2 is a portion of the connection electrode CE that is subjected to the laser irradiation process for repair. The second resistance portion CE2 is a portion of the connection electrode CE that is in contact with at least one of the first connection line CLa and the second connection line CLb. Therefore, the second resistance portion CE2 may be configured to selectively electrically disconnect a portion being in contact with the first connection line CLa and the second connection line CLb.

With reference to FIG. 3C, a second thickness d2, which is a thickness of the second resistance portion CE2, may be larger than a first thickness d1 that is a thickness of the first resistance portion CE1. For example, the second resistance portion CE2 may be formed by a process in which a diffusion phenomenon in which a temperature of the connection electrode CE is increased by laser beams and distances between indium (In) particles included in the connection electrode CE are increased occurs, and a volume of the corresponding portion is also increased. For example, the thickness of the second resistance portion CE2 may be increased by about 10% to 20% in comparison with the state made before the laser irradiation. However, the present specification is not limited thereto.

In this case, in the second resistance portion CE2 in which the distances between the indium (In) particles are increased, the movement of electric current decreases, such that the second resistance portion CE2 may have a larger resistance value than the first resistance portion CE1. Therefore, in the connection electrode CE, the second resistance portion CE2 may be configured to substantially electrically disconnect the transistor T and at least one of the first light-emitting element 120a and the second light-emitting element 120b.

Meanwhile, because the second resistance portion CE2 in the connection electrode CE is a portion where the distances between indium (In) particles are increased by the laser irradiation, an indium (In) density of the second resistance portion CE2 may be lower than an indium (In) density of the first resistance portion CE1. That is, the indium (In) density of the first resistance portion CE1 may be higher than the indium (In) density of the second resistance portion CE2.

With reference to FIGS. 3A to 5B, in the display device 100 according to the embodiment of the present specification, the plurality of connection lines CLa and CLb of the subpixel SP, which has a bright spot defect or a dark spot defect, include low-resistance portions CLa1 and CLb1 and high-resistance portions CLa2 and CLb2.

The low-resistance portions CLa1 and CLb1 are portions that are not subjected to the laser irradiation process for repair in the first connection line CLa and the second connection line CLb of the subpixel SP having a bright spot defect or a dark spot defect. The low-resistance portions CLa1 and CLb1 are portions that are entirely conductive, like the first connection line CLa and the second connection line CLb of the normal subpixel SP.

The high-resistance portions CLa2 and CLb2 are portions that are subjected to the laser irradiation process for repair in the first connection line CLa and the second connection line CLb. In case that at least one of the first light-emitting element 120a and the second light-emitting element 120b is defective, at least one of the first connection line CLa and the second connection line CLb may include the high-resistance portions CLa2 and CLb2. The high-resistance portions CLa2 and CLb2 are disposed on portions of the first connection line CLa and the second connection line CLb that adjoin the top surface of the connection electrode CE. For example, the high-resistance portions CLa2 and CLb2 may be formed by a process of irradiating contact hole portions, which are formed in the passivation layer 113 and the planarization layer 114 in order to electrically connect the first connection line CLa, the second connection line CLb, and the connection electrode CE, with laser beams.

For example, the high-resistance portions CLa2 and CLb2 may be formed by a process in which a diffusion phenomenon in which temperatures of the first connection line CLa and the second connection line CLb are increased by laser beams and distances between the indium (In) particles included in the first connection line CLa and the second connection line CLb are increased occurs, and a volume of the corresponding portion is also increased. For example, the thicknesses of the high-resistance portions CLa2 and CLb2 may be increased by about 10% to 20% in comparison with the state made before the laser irradiation. However, the present specification is not limited thereto.

In addition, a thickness of each of the high-resistance portions CLa2 and CLb2 may be larger than a thickness of each of the low-resistance portions CLa1 and CLb1. For example, as illustrated in FIG. 3C, a fourth thickness d4, which is a thickness of each of the high-resistance portions CLa2 and CLb2, may be larger than a third thickness d3 that is a thickness of each of the low-resistance portions CLa1 and CLb1. However, the present specification is not limited thereto.

In this case, in the high-resistance portions CLa2 and CLb2 in which the distances between the indium (In) particles are increased, the movement of electric current decreases, such that the high-resistance portions CLa2 and CLb2 may have higher resistance than the low-resistance portions CLa1 and CLb1. Therefore, the connection lines CLa and CLb, in which the high-resistance portions CLa2 and CLb2 are disposed, may be configured to substantially electrically disconnect the plurality of light-emitting elements 120a and 120b and the transistor T.

Meanwhile, because the high-resistance portions CLa2 and CLb2 are portions where the distances between the indium (In) particles are increased by the laser irradiation, an indium (In) density of the high-resistance portions CLa2 and CLb2 may be lower than an indium (In) density of the low-resistance portions CLa1 and CLb1. That is, the indium (In) density of the low-resistance portion CLa1 and CLb1 may be higher than the indium (In) density of the high-resistance portions CLa2 and CLb2.

With reference to FIGS. 3B, 3C, 4B, and 5B, the second resistance portion CE2 and the high-resistance portions CLa2 and CLb2 are disposed to overlap one another. That is, the second resistance portion CE2 and the high-resistance portions CLa2 and CLb2 may be formed simultaneously by the same laser irradiation process. Therefore, all the connection electrode CE, in which the second resistance portion CE2 is disposed, and the connection lines CLa and CLb, in which the high-resistance portions CLa2 and CLb2 are disposed, are substantially electrically disconnected, which may improve reliability of the laser repair.

For example, a process of forming the second resistance portion CE2 and the high-resistance portions CLa2 and CLb2 may include a process of irradiating laser beams to a contact hole portion through which the connection lines CLa and CLb, which are connected to a defective light-emitting element, and the connection electrode CE are electrically connected below the substrate 110. In this case, because all the connection electrode CE, the first connection line CLa, and the second connection line CLb are made of transparent materials, the connection lines CLa and CLb disposed on the connection electrode CE may also be irradiated with laser beams. Therefore, the second resistance portion CE2 and the high-resistance portions CLa2 and CLb2 may be formed simultaneously by the same laser irradiation process.

Meanwhile, for example, a short-wavelength laser with a wavelength value of 266 nm may be used as a laser used for the process of forming the second resistance portion CE2 and the high-resistance portions CLa2 and CLb2. In this case, in the case of a short-wavelength laser with a wavelength value of 266 nm, indium gallium zinc oxide (IGZO) has absorbency of 43%, and indium zinc oxide (IZO) has absorbency of 99%. That is, because indium gallium zinc oxide (IGZO) and indium zinc oxide (IZO) have absorption properties for the short-wavelength laser with a wavelength value of 266 nm, indium gallium zinc oxide (IGZO) and indium zinc oxide (IZO) may be used as materials of the connection lines CLa and CLb and the connection electrode CE that form the second resistance portion CE2 and the high-resistance portions CLa2 and CLb2 during the laser irradiation. However, the present specification is not limited thereto.

Hereinafter, a method of repairing the subpixel SP, in which defects occur in various cases, will be described more specifically.

First, with reference to FIGS. 3A to 3C, in case that a bright spot defect or a dark spot defect occurs on the first light-emitting element 120a, the contact hole portion, where the first connection line CLa and the connection electrode CE adjoin, is irradiated with laser beams. Further, the distances between the indium (In) particles included in the first connection line CLa and the connection electrode CE are increased by the laser irradiation, and the movement of electric current decreases, such that the high-resistance portion CLa2 and the second resistance portion CE2, which are portions with an increased resistance value, are formed. That is, the first connection line CLa has the high-resistance portion CLa2, and the connection electrode CE has the second resistance portion CE2 being in contact with the high-resistance portion CLa2. Therefore, because the first light-emitting element 120a, which has a defect, is electrically disconnected from the transistor T by the high-resistance portion CLa2 and the second resistance portion CE2, the defect occurring on the first light-emitting element 120a in the subpixel SP may not be visually recognized, and the subpixel SP may be repaired.

Next, with reference to FIGS. 4A and 4B, in case that a bright spot defect or a dark spot defect occurs on the second light-emitting element 120b, the contact hole portion, where the second connection line CLb and the connection electrode CE adjoin, is irradiated with laser beams. Further, the distances between the indium (In) particles included in the second connection line CLb and the connection electrode CE are increased by the laser irradiation, and the movement of electric current decreases, such that the high-resistance portion CLb2 and the second resistance portion CE2, which are portions with an increased resistance value, are formed. That is, the second connection line CLb has the high-resistance portion CLb2, and the connection electrode CE has the second resistance portion CE2 being in contact with the high-resistance portion CLb2. Therefore, the second light-emitting element 120b, which has a defect, is electrically disconnected from the transistor T by the high-resistance portion CLb2 and the second resistance portion CE2, such that the defect occurring on the second light-emitting element 120b in the subpixel SP may not be visually recognized, and the subpixel SP may be repaired.

Lastly, with reference to FIGS. 5A and 5B, in case that a bright spot defect or a dark spot defect occurs on both the first light-emitting element 120a and the second light-emitting element 120b, the contact hole portion, where the first connection line CLa and the connection electrode CE adjoin, and the contact hole portion, where the second connection line CLb and the connection electrode CE adjoin, are irradiated with laser beams. Further, the distances between the indium (In) particles included in the first connection line CLa, the second connection line CLb, and the connection electrode CE are increased by the laser irradiation, and the movement of electric current decreases, such that the high-resistance portions CLa2 and CLb2 and the plurality of second resistance portions CE2, which are portions with an increased resistance value, are formed. That is, the first connection line CLa and the second connection line CLb2 respectively have the high-resistance portions CLa2 and CLb2, and the connection electrode CE has the plurality of second resistance portions CE2 being in contact with the high-resistance portions CLa2 and CLb2. Therefore, because the first light-emitting element 120a and the second light-emitting element 120b, which have defects, are electrically disconnected from the transistor T by the high-resistance portions CLa2 and CLb2 and the plurality of second resistance portions CE2, the defects occurring on the first light-emitting element 120a and the second light-emitting element 120b in the subpixel SP may not be visually recognized, and the subpixel SP may be repaired.

In the display device configured such that the plurality of light-emitting areas is disposed in one subpixel to repair a bright spot defect or a dark spot defect, the bright spot defect or the dark spot defect may be repaired by a process of selectively separating lines or electrodes that electrically connect the plurality of light-emitting areas and the transistor connected to the plurality of light-emitting areas. In this case, for example, the method of electrically disconnecting the plurality of light-emitting areas and the transistor may be performed by a method of physically removing the lines or electrodes by emitting laser beams.

However, in case that the lines or electrodes are physically removed to repair a bright spot defect or a dark spot defect of the subpixel, the arrangement structure between the surrounding constituent elements is deformed by volumes of the removed lines or electrodes, which may cause a problem of a deterioration in reliability of the display device. Meanwhile, the problem of a bright spot defect or a dark spot defect of the subpixel and the deformation of the arrangement structure, which additionally occurs during the repair process, may become more severe in the top emission type display device in which a larger number of constituent elements are disposed above the light-emitting elements in the plurality of light-emitting areas.

In addition, in case that an additional repair part is disposed to repair a bright spot defect or a dark spot defect of the subpixel, there may occur an additional problem in that an area, in which a light-emitting area may be disposed, is reduced by the arrangement of the repair part.

Therefore, in the display device 100 according to the embodiment of the present specification, the first connection line CLa and the second connection line CLb are disposed to connect the connection electrode CE, the first anode 121a, and the second anode 121b, and the high-resistance portions CLa2 and CLb2 and the second resistance portion CE2 are disposed on the connection lines CLa and CLb and the connection electrode CE of the subpixel SP in which a defective light-emitting element is disposed, which may minimize a deterioration in reliability of the display device 100 that occurs during the repair process.

Specifically, in the display device 100 according to the embodiment of the present specification, the first connection line CLa is disposed to extend onto the connection electrode CE from the end of the first anode 121a, and the second connection line CLb is disposed to extend onto the connection electrode CE from the end of the second anode 121b. Therefore, the first connection line CLa and the second connection line CLb may electrically connect the first light-emitting element 120a and the second light-emitting element 120b to one transistor T. Therefore, the first connection line CLa and the second connection line CLb may each serve as the repair parts that repair the subpixel SP, in which a light-emitting element with a dark spot defect or a luminance defect is disposed, by selectively electrically disconnecting the first light-emitting element 120a, the second light-emitting element 120b, and the transistor T. Further, in case that at least one of the first light-emitting element 120a and the second light-emitting element 120b is defective, the connection lines CLa and CLb connected to the defective light-emitting element may include the high-resistance portions CLa2 and CLb2. In this case, because the high-resistance portions CLa2 and CLb2 increase the distances between the indium (In) particles and decrease the movement of electric current, the connection lines CLa and CLb, in which the high-resistance portions CLa2 and CLb2 are disposed, may be configured to substantially electrically disconnect the defective light-emitting element and the transistor T. That is, the first connection line CLa and the second connection line CLb of the display device 100 according to the embodiment of the present specification may be configured to substantially electrically disconnect the defective light-emitting element and the transistor T even without being physically removed. Therefore, it is possible to minimize the problem of the deformation of the arrangement structure of the surrounding constituent elements that occurs when the connection lines CLa and CLb are physically removed during the repair process of electrically disconnecting the transistor T and the defective light-emitting element. Therefore, in the display device 100 according to the embodiment of the present specification, the first connection line CLa and the second connection line CLb are disposed to connect the connection electrode CE, the first anode 121a, and the second anode 121b, and the high-resistance portions CLa2 and CLb2 are disposed on the connection lines CLa and CLb of the subpixel SP in which a defective light-emitting element is disposed, which may minimize a deterioration in reliability of the display device 100 that occurs during the repair process.

In addition, in the display device 100 according to the embodiment of the present specification, the contact hole portions, where the plurality of connection lines CLa and CLb and the connection electrode CE adjoin, are used as the repair points without adding a separate configuration for repair, which may minimize a reduction in light-emitting area.

Specifically, in the display device 100 according to the embodiment of the present specification, all the connection electrode CE, the first connection line CLa, and the second connection line CLb are made of transparent materials. Therefore, for example, the connection lines CLa and CLb disposed on the connection electrode CE may also be irradiated with laser beams by the process of irradiating laser beams from below the substrate 110. Therefore, the second resistance portion CE2 and the high-resistance portions CLa2 and CLb2 may be formed simultaneously by the same laser irradiation process. Therefore, because the contact hole portions, where the plurality of connection lines CLa and CLb and the connection electrode CE adjoin, may be electrically disconnected, the contact hole portions, where the plurality of connection lines CLa and CLb and the connection electrode CE adjoin, may be used as the repair points for repairing the subpixel with a bright spot defect or a dark spot defect even without adding a separate repair point. Therefore, in the display device 100 according to the embodiment of the present specification, the contact hole portions, where the plurality of connection lines CLa and CLb and the connection electrode CE adjoin, are used as the repair points without adding a separate configuration for repair, which may minimize or at least reduce a reduction in light-emitting area and provide the high-quality display device in which an aperture ratio of the light-emitting area is improved.

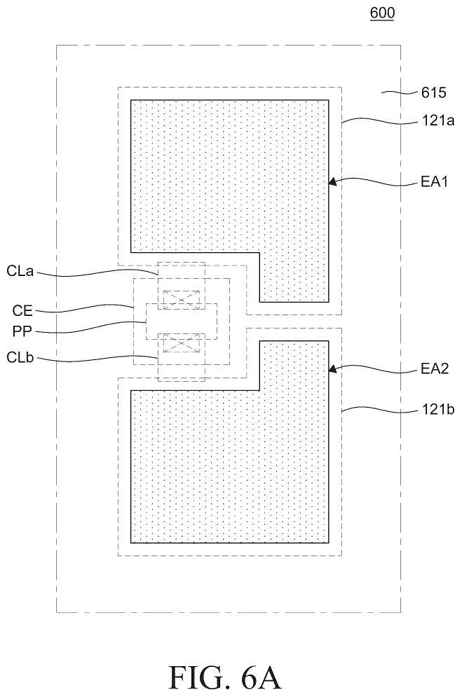

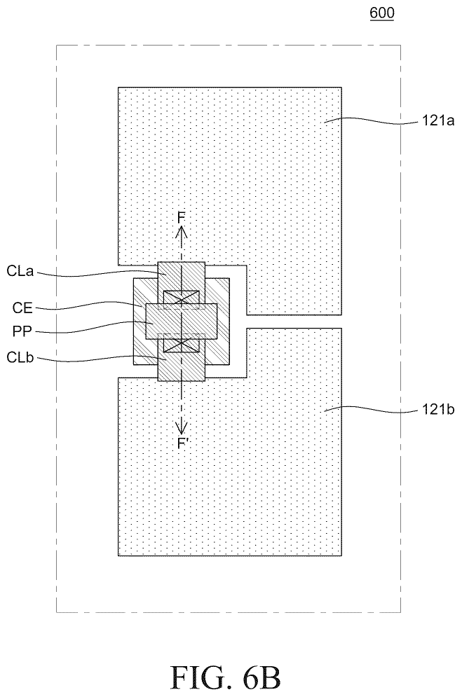

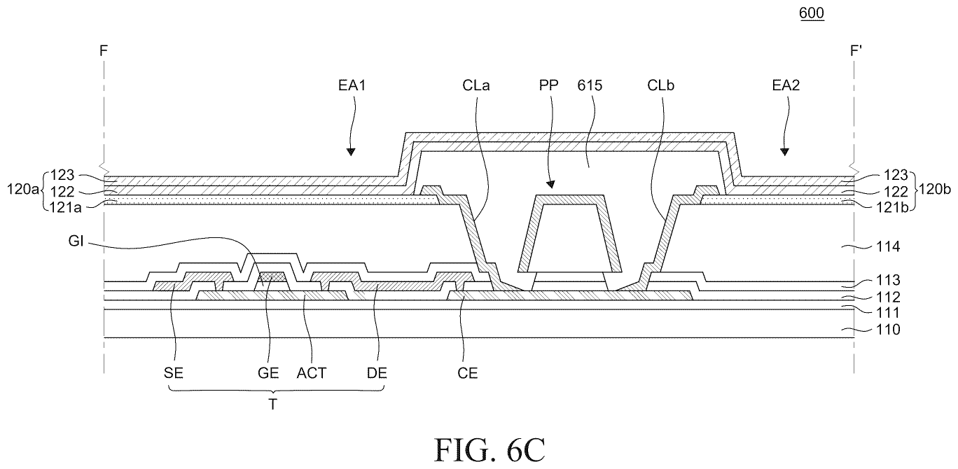

Hereinafter, a subpixel in which all the plurality of light-emitting elements are normal in a display device according to another embodiment of the present specification will be described in detail with reference to FIGS. 6A to 6C.

FIGS. 6A and 6B are enlarged top plan views of a subpixel in which both a first light-emitting element and a second light-emitting element are normal in a display device according to another embodiment of the present specification. FIG. 6C is a cross-sectional view taken along line F-F′ in FIG. 6B according to an embodiment of the present specification. For convenience of illustration, FIG. 6A illustrates only the first anode 121a, the second anode 121b, the connection electrode CE, the first connection line CLa, the second connection line CLb, a protruding portion PP, and a bank 615 among various constituent elements of a display device 600. For convenience of description, FIG. 6B is a view that does not illustrate the bank 615 in FIG. 6A. The display device 600 in FIGS. 6A to 6C is substantially identical in configuration to the display device 100 in FIGS. 1 to 5B, except that the protruding portion PP is further disposed in the subpixel SP. Therefore, repeated descriptions of the identical components will be omitted.

With reference to FIGS. 6A to 6C, the protruding portion PP is disposed between the first light-emitting area EA1 and the second light-emitting area EA2 in each of the subpixels SP of the display device 600 according to another embodiment of the present specification. The protruding portion PP is disposed in an area in which the first connection line CLa and the second connection line CLb are spaced apart from each other. The protruding portion PP is disposed to be spaced apart from the first connection line CLa and the second connection line CLb.

The protruding portion PP may include a plurality of layers. For example, the protruding portion PP may include the plurality of layers including the same material as the insulation layer 112, the passivation layer 113, the planarization layer 114, the first connection line CLa, and the second connection line CLb. For example, the protruding portion PP may be formed simultaneously with the process of forming the insulation layer 112, the passivation layer 113, the planarization layer 114, the first connection line CLa, and the second connection line CLb. However, the present specification is not limited thereto.

Meanwhile, with reference to FIG. 6C, the protruding portion PP is disposed in an undercut shape. Further, an end of the first connection line CLa and an end of the second connection line CLb are disposed in a lower area of the undercut shape of the protruding portion PP. In the lower area of the undercut shape of the protruding portion PP, the end of the first connection line CLa and the end of the second connection line CLb may be disposed on the connection electrode CE and electrically connected to the connection electrode CE.

With reference to FIG. 6C, the end of the first connection line CLa and the end of the second connection line CLb are disposed in a shape having a thickness that decreases toward the end. For example, the protruding portion PP may be configured to separate the first connection line CLa and the second connection line CLb by the undercut shape during the process of forming the protruding portion PP, the first connection line CLa, and the second connection line CLb. Therefore, the end of the first connection line CLa and the end of the second connection line CLb, which are separated by the undercut shape of the protruding portion PP, may be disposed in a shape having a smaller thickness than a portion that is not in contact with the connection electrode CE.

Meanwhile, FIGS. 6A to 6C illustrate a normal subpixel SP that does not have a defect and is not subjected to the repair process. In this case, in case that both the first light-emitting element 120a and the second light-emitting element 120b disposed in the subpixel SP are normal, the repair process is not performed on the first connection line CLa and the second connection line CLb disposed in the subpixel SP, such that both the first connection line CLa and the second connection line CLb may be conductive.

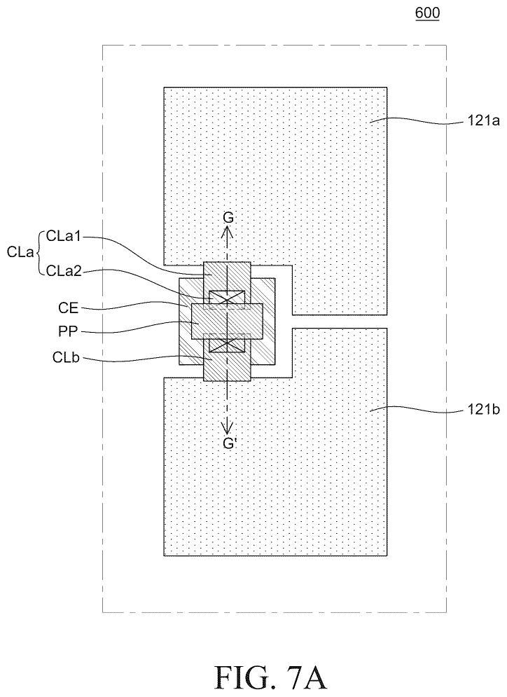

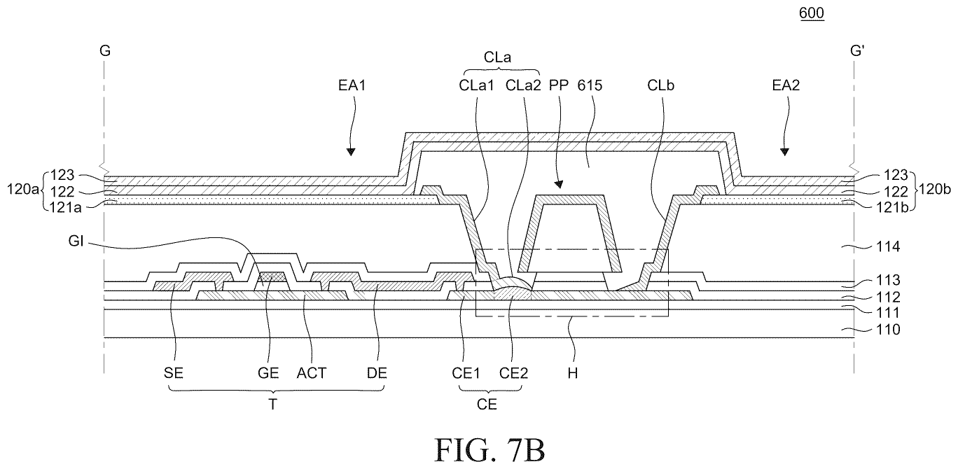

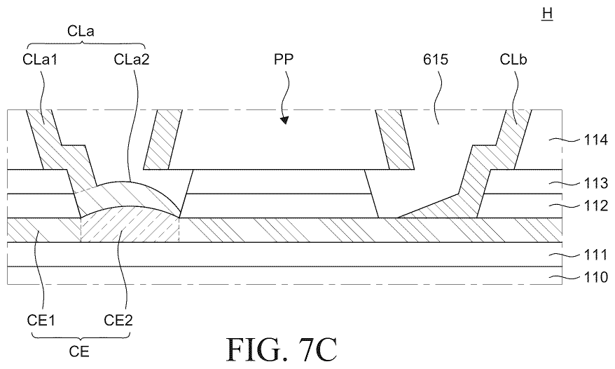

Hereinafter, a method of repairing a subpixel in which a defective light-emitting element is disposed in the display device according to another embodiment of the present specification will be described in detail with reference to FIGS. 7A to 9B.

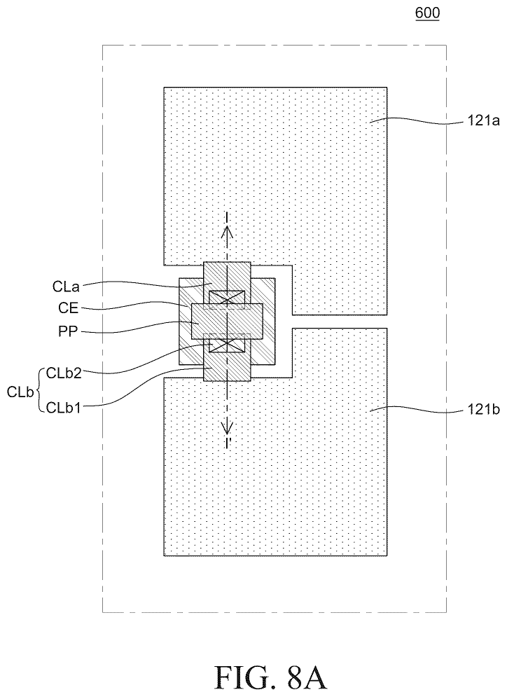

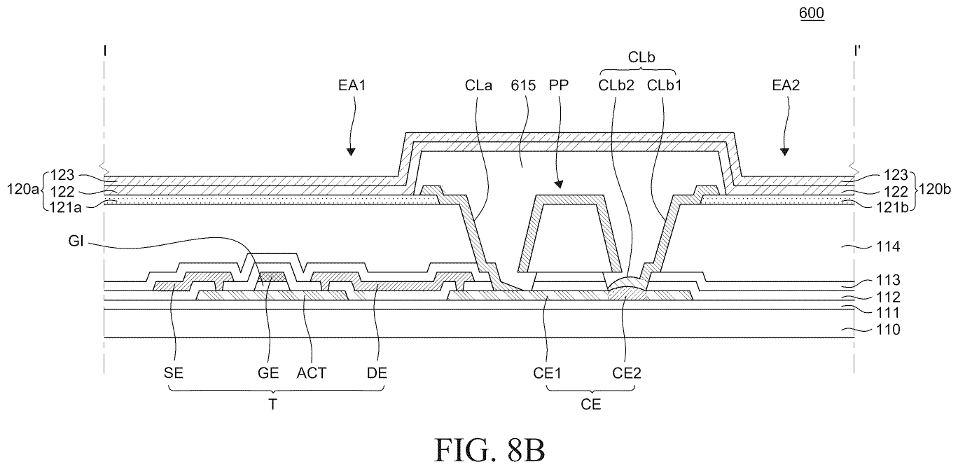

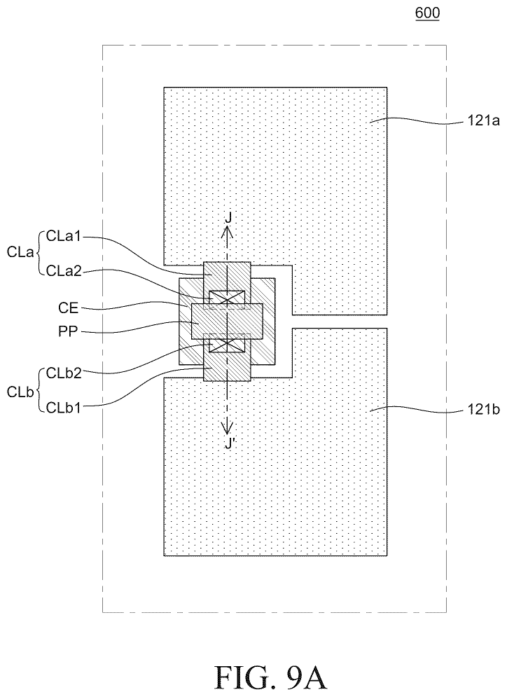

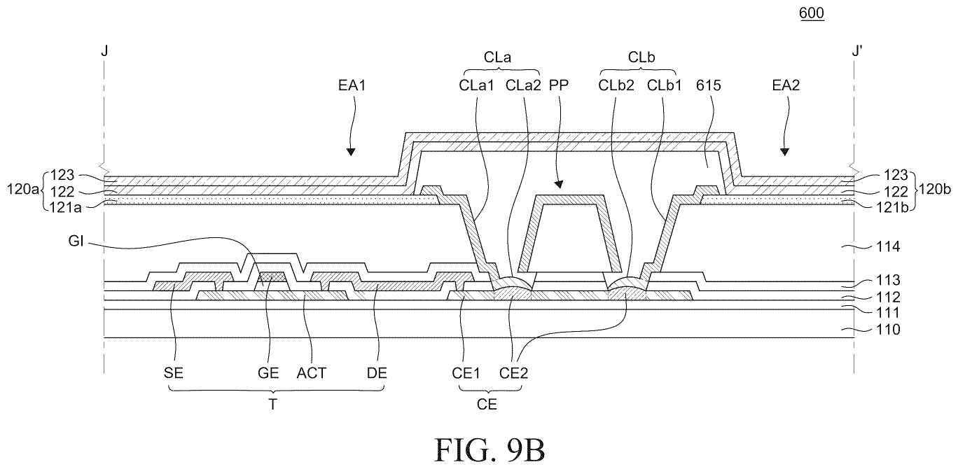

FIG. 7A is an enlarged top plan view of a subpixel in which a first light-emitting element is defective in the display device according to another embodiment of the present specification. FIG. 7B is a cross-sectional view taken along line G-G′ in FIG. 7A according to an embodiment of the present specification. FIG. 7C is an enlarged view of area H in FIG. 7B according to an embodiment of the present specification. FIG. 8A is an enlarged top plan view of a subpixel in which a second light-emitting element is defective in the display device according to another embodiment of the present specification. FIG. 8B is a cross-sectional view taken along line I-I′ in FIG. 8A according to an embodiment of the present specification. FIG. 9A is an enlarged top plan view of a subpixel in which a first light-emitting element and a second light-emitting element are defective in the display device according to another embodiment of the present specification. FIG. 9B is a cross-sectional view taken along line J-J′ in FIG. 9A according to an embodiment of the present specification. The display device 600 in FIGS. 7A to 9B is substantially identical in configuration to the display device 100 in FIGS. 1 to 5B, except that the protruding portion PP is further disposed in the subpixel SP. Therefore, repeated descriptions of the identical components will be omitted.

With reference to FIGS. 7A to 9B, in the display device 600 according to another embodiment of the present specification, the connection electrode CE of the subpixel SP with a bright spot defect or a dark spot defect includes the first resistance portion CE1 and the second resistance portion CE2, and the connection lines CLa and CLb of the subpixel SP with a bright spot defect or a dark spot defect include the low-resistance portions CLa1 and CLb1 and the high-resistance portions CLa2 and CLb2.

With reference to FIG. 7C, the end of the first connection line CLa and the end of the second connection line CLb are disposed in a shape having a thickness that decreases toward the end. Because the end of the first connection line CLa and the end of the second connection line CLb disposed on the connection electrode CE are disposed in a shape having a smaller thickness than a portion that is not in contact with the connection electrode CE, the indium (In) particles may be more sensitive to the laser beams. Therefore, the end of the first connection line CLa and the end of the second connection line CLb disposed on the connection electrode CE are disposed in a shape having a thickness that decreases toward the end, such that the end of the first connection line CLa and the end of the second connection line CLb may be configured to more easily electrically disconnect the plurality of light-emitting elements 120a and 120b and the transistor T.

Hereinafter, a method of repairing the subpixel SP, in which defects occur in various cases, will be described more specifically.

First, with reference to FIGS. 7A to 7C, in case that a bright spot defect or a dark spot defect occurs on the first light-emitting element 120a, the contact hole portion, where the first connection line CLa and the connection electrode CE adjoin, is irradiated with laser beams. Further, the distances between the indium (In) particles included in the first connection line CLa and the connection electrode CE are increased by the laser irradiation, and the movement of electric current decreases, such that the high-resistance portion CLa2 and the second resistance portion CE2, which are portions with an increased resistance value, are formed. That is, the first connection line CLa has the high-resistance portion CLa2, and the connection electrode CE has the second resistance portion CE2 being in contact with the high-resistance portion CLa2. Therefore, because the first light-emitting element 120a, which has a defect, is electrically disconnected from the transistor T by the high-resistance portion CLa2 and the second resistance portion CE2, the defect occurring on the first light-emitting element 120a in the subpixel SP may not be visually recognized, and the subpixel SP may be repaired.

Next, with reference to FIGS. 8A and 8B, in case that a bright spot defect or a dark spot defect occurs on the second light-emitting element 120b, the contact hole portion, where the second connection line CLb and the connection electrode CE adjoin, is irradiated with laser beams. Further, the distances between the indium (In) particles included in the second connection line CLb and the connection electrode CE are increased by the laser irradiation, and the movement of electric current decreases, such that the high-resistance portion CLb2 and the second resistance portion CE2, which are portions with an increased resistance value, are formed. That is, the second connection line CLb has the high-resistance portion CLb2, and the connection electrode CE has the second resistance portion CE2 being in contact with the high-resistance portion CLb2. Therefore, the second light-emitting element 120b, which has a defect, is electrically disconnected from the transistor T by the high-resistance portion CLb2 and the second resistance portion CE2, such that the defect occurring on the second light-emitting element 120b in the subpixel SP may not be visually recognized, and the subpixel SP may be repaired.

Lastly, with reference to FIGS. 9A and 9B, in case that a bright spot defect or a dark spot defect occurs on both the first light-emitting element 120a and the second light-emitting element 120b, the contact hole portion, where the first connection line CLa and the connection electrode CE adjoin, and the contact hole portion, where the second connection line CLb and the connection electrode CE adjoin, are irradiated with laser beams. Further, the distances between the indium (In) particles included in the first connection line CLa, the second connection line CLb, and the connection electrode CE are increased by the laser irradiation, and the movement of electric current decreases, such that the high-resistance portions CLa2 and CLb2 and the plurality of second resistance portions CE2, which are portions with an increased resistance value, are formed. That is, the first connection line CLa and the second connection line CLb2 have the high-resistance portions CLa2 and CLb2, and the connection electrode CE has the plurality of second resistance portions CE2 being in contact with the high-resistance portions CLa2 and CLb2. Therefore, because the first light-emitting element 120a and the second light-emitting element 120b, which have defects, are electrically disconnected from the transistor T by the high-resistance portions CLa2 and CLb2 and the plurality of second resistance portions CE2, the defects occurring on the first light-emitting element 120a and the second light-emitting element 120b in the subpixel SP may not be visually recognized, and the subpixel SP may be repaired.

In the display device 600 according to another embodiment of the present specification, the first connection line CLa and the second connection line CLb are disposed to connect the connection electrode CE, the first anode 121a, and the second anode 121b, and the high-resistance portions CLa2 and CLb2 and the second resistance portion CE2 are disposed on the connection lines CLa and CLb and the connection electrode CE of the subpixel SP in which a defective light-emitting element is disposed, which may minimize a deterioration in reliability of the display device 600 that occurs during the repair process.

Specifically, in the display device 600 according to another embodiment of the present specification, the first connection line CLa is disposed to extend onto the connection electrode CE from the end of the first anode 121a, and the second connection line CLb is disposed to extend onto the connection electrode CE from the end of the second anode 121b. Therefore, the first connection line CLa and the second connection line CLb may electrically connect the first light-emitting element 120a and the second light-emitting element 120b to one transistor T. Therefore, the first connection line CLa and the second connection line CLb may each serve as the repair parts that repair the subpixel SP, in which a light-emitting element with a dark spot defect or a luminance defect is disposed, by selectively electrically disconnecting the first light-emitting element 120a, the second light-emitting element 120b, and the transistor T. Further, in case that at least one of the first light-emitting element 120a and the second light-emitting element 120b is defective, the connection lines CLa and CLb connected to the defective light-emitting element may include the high-resistance portions CLa2 and CLb2. In this case, because the high-resistance portions CLa2 and CLb2 increase the distances between the indium (In) particles and decrease the movement of electric current, the connection lines CLa and CLb, in which the high-resistance portions CLa2 and CLb2 are disposed, may be configured to substantially electrically disconnect the defective light-emitting element and the transistor T. That is, the first connection line CLa and the second connection line CLb of the display device 600 according to another embodiment of the present specification may be configured to substantially electrically disconnect the defective light-emitting element and the transistor T even without being physically removed. Therefore, it is possible to minimize or at least reduce the problem of the deformation of the arrangement structure of the surrounding constituent elements that occurs when the connection lines CLa and CLb are physically removed during the repair process of electrically disconnecting the transistor T and the defective light-emitting element. Therefore, in the display device 600 according to another embodiment of the present specification, the first connection line CLa and the second connection line CLb are disposed to connect the connection electrode CE, the first anode 121a, and the second anode 121b, and the high-resistance portions CLa2 and CLb2 are disposed on the connection lines CLa and CLb of the subpixel SP in which a defective light-emitting element is disposed, which may minimize or at least reduce a deterioration in reliability of the display device 600 that occurs during the repair process.

In addition, in the display device 600 according to another embodiment of the present specification, the contact hole portions, where the plurality of connection lines CLa and CLb and the connection electrode CE adjoin, are used as the repair points without adding a separate configuration for repair, which may minimize or at least reduce a reduction in light-emitting area.

Specifically, in the display device 600 according to another embodiment of the present specification, all the connection electrode CE, the first connection line CLa, and the second connection line CLb are made of transparent materials. Therefore, for example, the connection lines CLa and CLb disposed on the connection electrode CE may also be irradiated with laser beams by the process of irradiating laser beams from below the substrate 110. Therefore, the second resistance portion CE2 and the high-resistance portions CLa2 and CLb2 may be formed simultaneously by the same laser irradiation process. Therefore, because the contact hole portions, where the plurality of connection lines CLa and CLb and the connection electrode CE adjoin, may be electrically disconnected, the contact hole portions, where the plurality of connection lines CLa and CLb and the connection electrode CE adjoin, may be used as the repair points for repairing the subpixel with a bright spot defect or a dark spot defect even without adding a separate repair point. Therefore, in the display device 600 according to another embodiment of the present specification, the contact hole portions, where the plurality of connection lines CLa and CLb and the connection electrode CE adjoin, are used as the repair points without adding a separate configuration for repair, which may minimize a reduction in light-emitting area and provide the high-quality display device in which an aperture ratio of the light-emitting area is improved.

The exemplary embodiments of the present disclosure can also be described as follows:

According to an aspect of the present disclosure, a display device may include: a substrate; a transistor disposed on the substrate; a connection electrode electrically connected to a source electrode or a drain electrode of the transistor; a planarization layer disposed on the transistor and the connection electrode; a plurality of light-emitting elements disposed on the planarization layer; and a plurality of connection lines configured to adjoin the connection electrode and the plurality of light-emitting elements, in which the plurality of light-emitting elements includes a first light-emitting element and a second light-emitting element, and in which the plurality of connection lines are made of a conductive oxide, disposed between the first light-emitting element and the second light-emitting element, and configured to cover an end of an anode of the first light-emitting element and an end of an anode of the second light-emitting element.

Each of the plurality of connection lines may be in contact with a top surface of the connection electrode through a contact hole formed in the planarization layer.

The plurality of connection lines may comprise a first connection line electrically connected to the first light-emitting element; and a second connection line electrically connected to the second light-emitting element.

The first connection line and the second connection line may be spaced apart from each other.

The first connection line and the second connection line may be in contact with one connection electrode.

The display device may further comprise a protruding portion disposed in an area in which the first connection line and the second connection line are spaced apart from each other,

An end of the first connection line and an end of the second connection line may be disposed on the connection electrode.

The end of the first connection line and the end of the second connection line each may have a shape having a thickness that decreases toward an end thereof on the connection electrode.

The connection electrode may be disposed on the same layer as an active layer of the transistor.

The connection electrode may include a transparent oxide semiconductor material and may be configured to have conductivity.

The connection electrode may include indium (In).

The plurality of connection lines may include indium (In).

The conductive oxide may be a transparent conductive oxide.

According to an aspect of the present disclosure, a display device may include: a substrate on which a plurality of subpixels are disposed; a transistor disposed in each of the plurality of subpixels on the substrate; a connection electrode electrically connected to a source electrode or a drain electrode of the transistor; a planarization layer disposed on the transistor and the connection electrode; a first light-emitting element and a second light-emitting element disposed on the planarization layer in one subpixel; and a plurality of connection lines configured to electrically connect the first light-emitting element, the second light-emitting element, and the connection electrode, in which the plurality of connection lines are made of a conductive oxide, and configured to cover an end of an anode of the first light-emitting element and an end of an anode of the second light-emitting element disposed in the one subpixel, and in which at least one of the plurality of connection lines comprises a low-resistance portion, and a high-resistance portion having a higher resistance value than the low-resistance portion.

Each of the plurality of connection lines may be in contact with a top surface of the connection electrode through a contact hole formed in the planarization layer.

The high-resistance portion may adjoin a top surface of the connection electrode.

A thickness of the high-resistance portion may be larger than a thickness of the low-resistance portion.

The plurality of connection lines may include indium (In).

An indium (In) density of the low-resistance portion may be higher than an indium density of the high-resistance portion.

The connection electrode may comprise a first resistance portion; and a second resistance portion having a higher resistance value than the first resistance portion and being in contact with the high-resistance portion.

The connection electrode may include indium (In).

The indium (In) density of the first resistance portion may higher than an indium (In) density of the second resistance portion.

The plurality of connection lines may comprise a first connection line electrically connected to the first light-emitting element; and a second connection line electrically connected to the second light-emitting element.

The first connection line and the second connection line may be spaced apart from each other.

The first connection line and the second connection line may be in contact with one connection electrode.

The display device may further comprise a protruding portion disposed in an area in which the first connection line and the second connection line are spaced apart from each other.

An end of the first connection line and an end of the second connection line may be disposed on the connection electrode.

The end of the first connection line and the end of the second connection line each may have a shape having a thickness that decreases toward an end thereof on the connection electrode.

The connection electrode may be disposed on the same layer as an active layer of the transistor.

The connection electrode may include a transparent oxide semiconductor material and may be configured to have conductivity.

The conductive oxide may be a transparent conductive oxide.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate;
a transistor on the substrate;
a connection electrode electrically connected to a source electrode or a drain electrode of the transistor;
a planarization layer on the transistor and the connection electrode;
a plurality of light-emitting elements on the planarization layer; and
a plurality of connection lines that adjoin the connection electrode and the plurality of light-emitting elements,
wherein the plurality of light-emitting elements comprise a first light-emitting element and a second light-emitting element, and
wherein the plurality of connection lines include a conductive oxide, disposed between the first light-emitting element and the second light-emitting element, and cover an end of an anode of the first light-emitting element and an end of an anode of the second light-emitting element.

2. The display device of claim 1, wherein each of the plurality of connection lines is in contact with a top surface of the connection electrode through a contact hole in the planarization layer.

3. The display device of claim 1, wherein the plurality of connection lines comprises:
a first connection line electrically connected to the first light-emitting element; and
a second connection line electrically connected to the second light-emitting element, and
wherein the first connection line and the second connection line are spaced apart from each other.

4. The display device of claim 3, wherein the first connection line and the second connection line are in contact with the connection electrode.

5. The display device of claim 3, further comprising:
a protruding portion in an area in which the first connection line and the second connection line are spaced apart from each other,
wherein an end of the first connection line and an end of the second connection line are on the connection electrode.

6. The display device of claim 5, wherein the end of the first connection line and the end of the second connection line each have a shape having a thickness that decreases toward an end thereof on the connection electrode.

7. The display device of claim 1, wherein the connection electrode is on a same layer as an active layer of the transistor.

8. The display device of claim 7, wherein the connection electrode includes a transparent oxide semiconductor material and is conductive.

9. The display device of claim 8, wherein the connection electrode includes indium.

10. The display device of claim 1, wherein the plurality of connection lines includes indium.

11. The display device of claim 1, wherein the conductive oxide is a transparent conductive oxide.

12. A display device comprising:
a substrate on which a plurality of subpixels are disposed;
a transistor disposed in each of the plurality of subpixels on the substrate;
a connection electrode electrically connected to a source electrode or a drain electrode of the transistor;
a planarization layer on the transistor and the connection electrode;
a first light-emitting element and a second light-emitting element on the planarization layer in one subpixel; and
a plurality of connection lines that electrically connect the first light-emitting element, the second light-emitting element, and the connection electrode,
wherein the plurality of connection lines include a conductive oxide, and cover an end of an anode of the first light-emitting element and an end of an anode of the second light-emitting element disposed in the one subpixel, and
wherein at least one of the plurality of connection lines comprises a low-resistance portion, and a high-resistance portion having a higher resistance value than the low-resistance portion.

13. The display device of claim 12, wherein each of the plurality of connection lines is in contact with a top surface of the connection electrode through a contact hole in the planarization layer.

14. The display device of claim 12, wherein the high-resistance portion adjoins a top surface of the connection electrode.

15. The display device of claim 12, wherein a thickness of the high-resistance portion is larger than a thickness of the low-resistance portion.

16. The display device of claim 12, wherein the plurality of connection lines include indium.

17. The display device of claim 16, wherein an indium density of the low-resistance portion is higher than an indium density of the high-resistance portion.

18. The display device of claim 12, wherein the connection electrode comprises:
a first resistance portion; and
a second resistance portion having a higher resistance value than the first resistance portion and being in contact with the high-resistance portion.

19. The display device of claim 18, wherein the connection electrode includes indium.

20. The display device of claim 19, wherein an indium density of the first resistance portion is higher than an indium density of the second resistance portion.

21. The display device of claim 12, wherein the plurality of connection lines comprises:
a first connection line electrically connected to the first light-emitting element; and
a second connection line electrically connected to the second light-emitting element, and
wherein the first connection line and the second connection line are spaced apart from each other.

22. The display device of claim 21, wherein the first connection line and the second connection line are in contact with one connection electrode.

23. The display device of claim 21, further comprising:
a protruding portion in an area in which the first connection line and the second connection line are spaced apart from each other,
wherein an end of the first connection line and an end of the second connection line are on the connection electrode.

24. The display device of claim 23, wherein the end of the first connection line and the end of the second connection line each have a shape having a thickness that decreases toward an end thereof on the connection electrode.

25. The display device of claim 12, wherein the connection electrode is on a same layer as an active layer of the transistor.

26. The display device of claim 25, wherein the connection electrode includes a transparent oxide semiconductor material and is conductive.

27. The display device of claim 12, wherein the conductive oxide is a transparent conductive oxide.
